(19) United States
(12) Patent Application Publication
(10) Pub. No.: US 2012/0228651 A1
(43) Pub. Date: Sep. 13, 2012

(54) LIGHT-EMITTING-DIODE ARRAY

(75) Inventors: Ray-Hua Horng, Taichung City (TW); Yi-An Lu, Chiayi City (TW); Heng Liu, Sunnyvale, CA (US)

(73) Assignees: NCKU RESEARCH AND DEVELOPMENT FOUNDATION, Tainan City (TW); PHOSTEK, INC., Taipei City (TW)

(21) Appl. No.: 13/481,299

(22) Filed: May 25, 2012

Related U.S. Application Data
(63) Continuation-in-part of application No. 12/948,504, filed on Nov. 17, 2010, now Pat. No. 8,193,546.

(51) Int. Cl. H01L 33/50; H01L 33/08

(52) U.S. Cl. 257/93; 438/34; 257/E33.061; 257/E33.066

(57) ABSTRACT

A light-emitting-diode (LED) array includes a first LED unit having a first electrode and a second LED unit having a second electrode. The first LED unit and the second LED unit are positioned on a common substrate and are separated by a gap. Two or more polymer materials form a multi-layered structure in the gap. A first polymer material substantially fills a lower portion of the gap and at least one additional polymer material substantially fills a remainder of the gap above the first polymer material. A kinematic viscosity of the first polymer material is less than a kinematic viscosity of the at least one additional polymer material. An interconnect, positioned on top of the at least one additional polymer material, electrically connects the first electrode and the second electrode.

### PRIORITY CLAIM

This patent application is a continuation-in-part of U.S. patent application Ser. No. 12/948,504 entitled “LIGHT-EMITTING-DIODE ARRAY AND METHOD FOR MANUFACTURING THE SAME” to Horng et al. filed on Nov. 17, 2010.

### BACKGROUND

1. Field of the Invention

The present invention relates to a semiconductor light emitting component, and more particularly to a light emitting diode (LED) array and a method for manufacturing the LED array.

2. Description of Related Art

A light-emitting diode (LED) is a semiconductor diode based light source. When a diode is forward biased (switched on), electrons are able to recombine with holes within the device, releasing energy in the form of photons. This effect is called electroluminescence and the color of the light (corresponding to the energy of the photon) is determined by the energy gap of the semiconductor. When used as a light source, the LED presents many advantages over incandescent light sources. These advantages include lower energy consumption, longer lifetime, improved robustness, smaller size, faster switching, and greater durability and reliability.

FIG. 1 is a perspective view of LED die 100. LED die 100 includes a substrate 102, an N-type layer 110, a light-emitting layer 125, and a p-type layer 130. N-contact 115 and p-contact 135 are formed on the n-type layer 110 and the p-type layer 130, respectively, for making electrical connections thereto. When a proper voltage is applied to the n- and p-contacts 115 and 135, electrons depart the n-type layer 110 and combine with holes in the light-emitting layer 125. The electron-hole combination in the light-emitting layer 125 generates light. Sapphire is a common material for the substrate 102. The n-type layer 110 may be made of, for example, AlGaN doped with Si or GaN doped with Si. The p-type layer 240 may be made of, for example, AlGaN doped with Mg or GaN doped with Mg. The light emitting layer 125 is typically formed by a single quantum well or multiple quantum wells (e.g., InGaN/GaN).

In some cases, a series or parallel LED array is formed on an insulating or highly resistive substrate (e.g., sapphire, SiC, or other III-nitride substrates). The individual LEDs are separated from each other by gaps, and interconnects deposited on the array electrically connect the contacts of the individual LEDs in the arrays. Typically, to ensure complete electrical isolation of individual LEDs, a dielectric material is deposited over the LED array before forming the interconnects, then the dielectric material is patterned and removed in places to open contact holes on n-type layer and p-type layer. Dielectric material is left in the gap between the individual LEDs on the substrate and on the mesa walls between the exposed p-type layer and n-type layer of each LED. Dielectric material may be, for example, oxides of silicon, nitrides of silicon, oxynitrides of silicon, aluminum oxide, or any other suitable dielectric material.

However, deposition of dielectric material is a slow and costly process. Moreover, subsequently formed interconnects may pose reliability concerns due to complex profiles and sharp corners of the interconnects. As such, what is desired is a system and method for manufacturing an LED array device cost-effectively and with improved long term reliability.

### SUMMARY

In certain embodiments, a light-emitting-diode (LED) array includes a first LED unit having a first electrode and a second LED unit having a second electrode. The first LED unit and the second LED unit are positioned on a common substrate and are separated by a gap. Two or more polymer materials form a multi-layered structure in the gap. A first polymer material substantially fills a lower portion of the gap and at least one additional polymer material substantially fills a remainder of the gap above the first polymer material. A kinematic viscosity of the first polymer material is less than a kinematic viscosity of the at least one additional polymer material. An interconnect, positioned on top of the at least one additional polymer material, electrically connecting the first electrode and the second electrode.

In certain embodiments, a method for forming a light-emitting-diode (LED) array includes forming an LED structure on a substrate and dividing the LED structure into at least a first LED unit and a second LED unit with a gap between the first LED unit and the second LED unit. A first polymer material is deposited into the gap between the first LED unit and the second LED unit to substantially fill a lower portion of the gap. At least one additional polymer material is deposited to substantially fill a remainder of the gap above the first polymer material. An interconnect is formed on top of the at least one additional polymer material to electrically connect a first electrode of the first LED unit and a second electrode of the second LED unit.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 is a perspective view of an LED die.

FIGS. 2A and 2B depict schematic, top views of embodiments of light emitting diode arrays formed on a single substrate.

FIG. 3 depicts a schematic, partial, cross-sectional view of the LED array shown in FIG. 2B.

FIGS. 4A-4C depict an embodiment of a process for forming an LED array that uses a polymer to fill up a gap between LED devices.

FIG. 5 illustrates an embodiment of an LED array with a trench formed in the substrate between two LED devices.

FIGS. 6A and 6B illustrate some alternative embodiments of interconnect patterns.

FIG. 7 illustrates an embodiment of an LED chip flip mounted on a board.

FIG. 8 depicts an embodiment of an LED array with spherical microstructures in the polymer material filling the gap between two LED devices.

FIG. 9 depicts an embodiment of an LED array with pyramid microstructures in the polymer material filling the gap between two LED devices.

FIG. 10 illustrates an embodiment of an LED array with two polymer materials filling a gap between two LED devices.

FIG. 11 depicts an embodiment of an interconnect formed above a polymer layer with a selected thickness above a gap and a selected thickness above a pad.

FIG. 12 depicts a side-view representation of an LED unit with vertically stacked epitaxial structures.

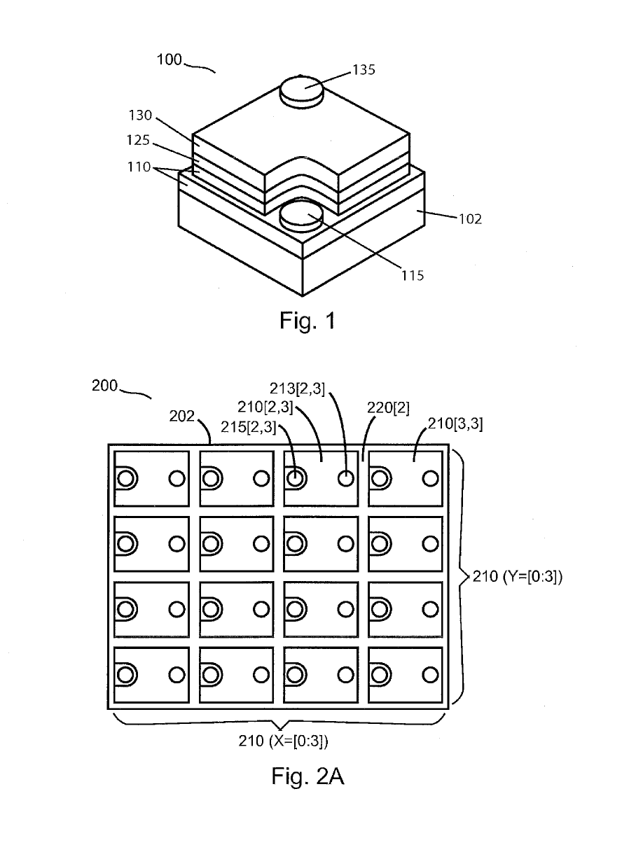

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

The present invention discloses an LED array structure and a process method for manufacturing the LED array. The LED array is formed from multiple LED devices for producing significant amounts of light at relatively low current density. Low current density generates less heat and allows polymer materials to be used in the LED array. Details of the LED array structure and the process for manufacturing the LED array are described hereinafter.

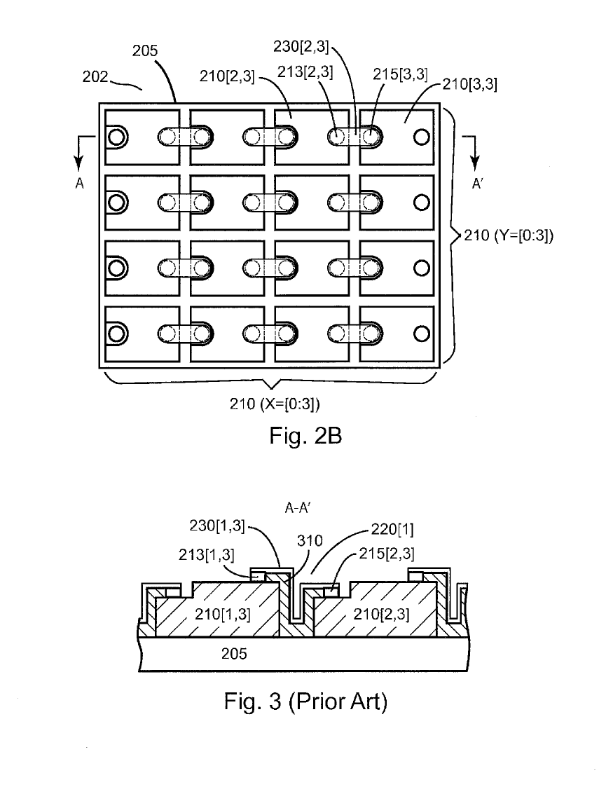

FIGS. 2A and 2B depict schematic, top views of embodiments of light emitting diode arrays 200 formed on single, common substrate 205. Referring to FIG. 2A, LED array 200 includes a number of light emitting diode (LED) devices 210 arranged in rows and columns. In the depicted embodiment, LED devices 210 are arranged in, but not limited to, four rows and in four columns. The numeral [X, Y] represents a position of LED device 210 in X column and in Y row (X=0, 1, 2, 3; Y=0, 1, 2, 3). Thus, the numeral [0:3, 0:3] can represent LED devices 210 in all positions of the LED array 200. Each of LED devices 210 has a mesa-shaped configuration. LED devices 210 are spatially separated from each other by either a laser etching method, a dicing or cutting saw, or an inductively coupled plasma reactive ion etching (ICP-RIE) method. For example, gap 220[2] is formed between neighboring LED devices 210[2, 3] and 210[3, 3]. LED devices 210 typically have two electrodes. For example, LED device 210[2, 3] has two electrodes (e.g., pads 213[2, 3] and 215[2, 3]) serving as an anode and a cathode, respectively, of the LED device. The electrodes can be formed on p-GaN and n-GaN (either p-side up or n-side up). One LED device's anode pad is placed close to a neighboring LED device's cathode pad such that LED devices 210 can be easily connected in series.

Referring now to FIG. 2B, pad 213[2, 3] and pad 215[3, 3] are connected by interconnect 230[2, 3]. Pads 213, 215, as well as interconnect 230, are typically formed by a metal. Pads 213, 215 and interconnect 230 may not necessarily be formed by the same metal.

FIG. 3 depicts a schematic, partial, cross-sectional view of LED array 202 at a location A-A′shown in FIG. 2B. On single substrate 205, multiple LED devices 210 are built with cross-sections of two adjacent ones, 210[1, 3] and 210[2, 3], shown in FIG. 3. Pad 213[1, 3], for example, is an anode of LED device 210[1, 3] and pad 215[2, 3] is a cathode of LED device 210[2, 3]. Conventionally, oxide layer 310 is formed in gap 220[1] between LED devices 210 to electrically isolate pads 213 and 215 from adjacent structures. Then, metal interconnect 230[1, 3] is formed on top of oxide layer 310 to connect pads 213[1, 3] and 215[2, 3]. Because of the depth of gap 220, however, oxide layer 310 can not fully fill the gap. Further, the profile of metal interconnect 230 is complicated and has a number of sharp corners. Thus, metal interconnect 230 is prone to being broken and the reliability of conventional LED array 202 is reduced.

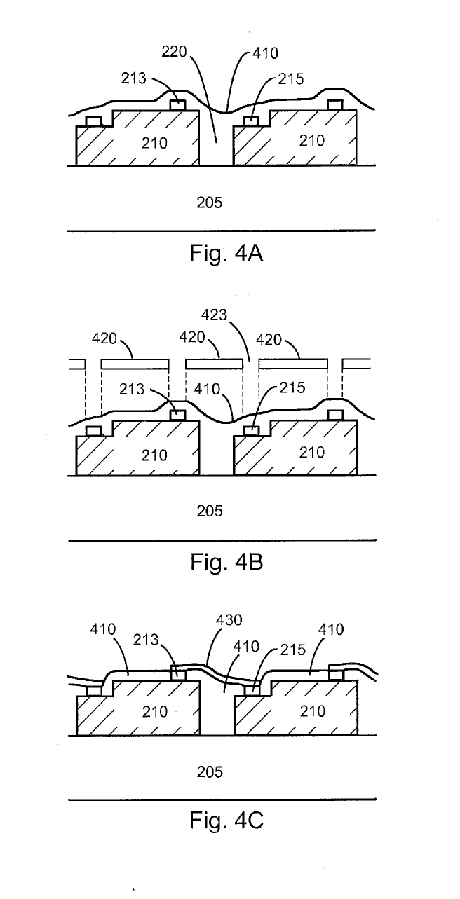

FIGS. 4A-4C depict an embodiment of a process for forming an LED array that uses a polymer to fill up gap 220 between LED devices 210. Because the LED devices described herein are intended to be used at high efficiency with little heat generated, it is feasible to leave polymer material in a finished LED device.

Beginning with FIG. 4A, after each individual LED device 210 and respective pads 213 and 215 are formed, polymer layer 410 is deposited over the LED devices. The polymer layer 410 fills up gap 220. Polymer 410 may be photoresist, such as polymethylglutarimide (PMGI) or SU-8. In certain embodiments, the refractive index of polymer layer 410 ranges from 1 to 2.6 (between air and semiconductor) to enhance light extraction. Optical transparency of polymer layer 410 may be equal to or more than 90% (e.g., equal to or more than 99%). Typically, a thickness of polymer layer 410 measured on top of anode 308 is approximately 2 microns. In some embodiments, polymer layer 410 is pre-mixed with phosphor (about 30 weight percentage loading) to adjust the output light color. However, the relative dimension between polymer coating thickness and phosphor particle size should be coordinated. For example, when a thickness of polymer layer 410 at pad 213 is about 3 microns, proper phosphor particle size is approximately 3 microns or less.

Next, as shown in FIG. 4B, patterned mask 420 is applied over polymer layer 410. Mask 420 may have openings 423 at the locations of pads 213 and 215 to allow the removal of polymer layer 410 thereon. In some embodiments, the polymer removal process smooths out the surface profile of polymer layer 410.

After the polymer removal process and pads 213 and 215 are exposed, a surface hydrophilic modification is performed on the polymer surface (e.g., oxygen plasma) to transform the originally hydrophobic surface into hydrophilic surface. Therefore, a subsequently formed metal-based interconnect can have improved adhesion to polymer layer 410.

Subsequently, as shown in FIG. 4C, interconnect 430 is formed on top of polymer layer 410 to connect pad 213 and pad 215. In certain embodiments, pad 213 and pad 215 have different vertical heights above the surface of substrate 205. Because of the smooth surface profile of polymer layer 410, the subsequently formed metal-based interconnect 430 may have a thin and smooth profile with improved endurance. The thin and smooth profile may provide improved performance and reliability as compared to the conventional interconnect with complex profiles and sharp corners depicted in FIG. 3. Even though the fragileness of the conventional interconnect 230 can be slightly improved by increasing the thickness of the interconnect 230, this is done at increased cost due to both additional material used and additional processing time.

In certain embodiments, as mentioned above, LED devices 210 are intended to be used at high efficiency with little heat generated. Thus, metals with lower melting points, such as Al, In, Sn, or related alloy metals can be used to form the major component of interconnect 430 (equal to or more than 90 vol %). Using such metal may further lower the cost of producing LED array 200. Fabrication processes, such as chemical vapor deposition, sputtering, or evaporation of the metal, can be used for forming interconnect 430. In one embodiment, three layers of metal (Ti/Al/Pt) are sputtered to form interconnect 430.

In some embodiments, a mixture of metal powder and polymer (e.g. silver paste) is used to form interconnect 430. A corresponding fabrication process may be a screen printing or a stencil printing process with even lower manufacturing cost.

In certain embodiments, the smoothness of polymer layer 410 allows the sizes of the pads 213, 215 and interconnect 430 to be smaller than the conventional ones shown in FIG. 3. Reducing the sizes of the pads and interconnect may provide less shielding of the LED area.

In addition to the aforementioned providing a smooth surface, in some embodiments, polymer layer 410 absorbs and dissipates heat from neighboring LED devices 210. Mixing polymer layer 410 with some special materials such as ceramics and carbon-based nanostructures may especially absorb and dissipate heat from neighboring LED devices 210. Ceramics and carbon-based nanostructures absorb heat energy and emit it as far-infrared wavelength energy Infrared radiation is a form of electromagnetic radiation with wavelengths longer than those at the red-end of the visible portion of the electromagnetic spectrum but shorter than microwave radiation. This wavelength range spans roughly 1 to several hundred microns, and is loosely subdivided—no standard definition exists—into near-infrared (0.7-1.5 microns), mid-infrared (1.5-5 microns), and far-infrared (5 to 1000 microns).

Ceramics which are inorganic oxides, nitrides, or carbides are considered as the most effective far-infrared ray emitting bodies. A number of studies on ceramic far-infrared ray emitting bodies have been reported including studies on zirconia, titania, alumina, zinc oxides, silicon oxides, boron nitride, and silicon carbides. Oxides of transition elements such as MnO₂, Fe₂O₃, CuO, CoO, and the like are considered more effective far-infrared ray emitting bodies. Other far-infrared ray emitting body includes carbon-based nanostructures such as carbon nanocapsules and carbon nanotubes, which also show a high degree of radiation activity. These materials are very close to a black body exhibiting a high degree of radiation activity throughout the entire infrared range. In certain embodiments, polymer layer 410 is pre-mixed with ceramics or carbon-based nanostructures that absorb the heat from nearby LED devices 210 and/or phosphors. These structures then dissipate the heat as far-infrared radiation. This characteristic may be used to allow heat to escape from LED devices 210 even when the LED devices are in a sealed enclosure without heat sinks or cooling fans. Of course, the addition of heat sinks or cooling fans heat may provide better heat dissipation.

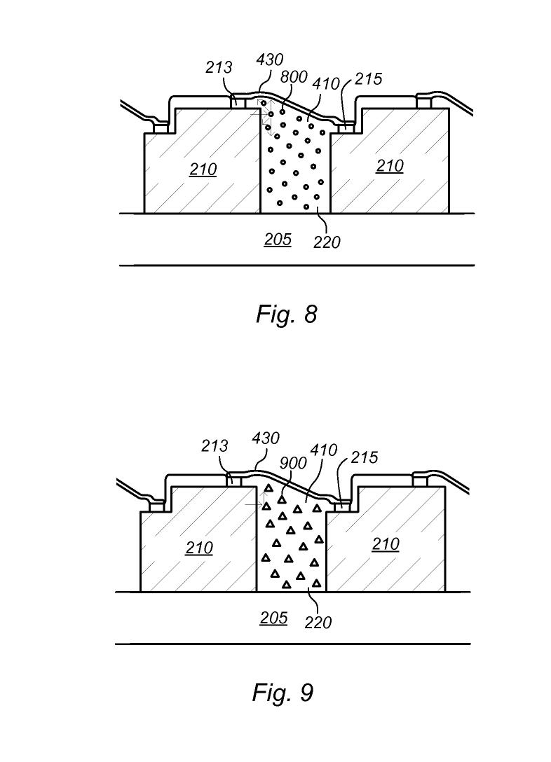

In certain embodiments, microsctructures are added to polymer material 410 to increase light extraction from LED devices 210 and LED array 200. The microstructures may, for example, be mixed with polymer material 410 before deposition of the polymer material on LED array 200. FIG. 8 depicts an embodiment of an LED array with spherical microstructures 800 in polymer material 410 filling gap 220 between two LED devices 210. FIG. 9 depicts an embodiment of an LED array with pyramid microstructures 900 in polymer material 410 filling gap 220 between two LED devices 210. While spherical and pyramid microstructures are shown in FIGS. 8 and 9, it is to be understood that other shapes may be contemplated. For example, tetrahedral or other polygonal microstructures may be used in polymer material 410 that provide similar advantages to the spherical and pyramid microstructures described herein.

In certain embodiments, microstructures 800 and/or microstructres 900 are transparent. Microstructures 800 and/or microstructures 900 may include edges or surfaces that reflect light. For example, as shown by the arrows in FIG. 8, spherical microstructures 800 may reflect (scatter) light from LED device 210 in multiple directions. As shown by the arrows in FIG. 9, pyramid microstructures 900, may also reflect light from LED device 210. As shown in FIG. 9, pyramid microstructures 900 may have a common orientation (e.g., one corner of each pyramid is oriented substantially vertically). Such an orientation may reflect light in a desired direction (e.g., upward out of the LED array). The desired direction may be the same direction as the orientation of the corner of each pyramid. In certain embodiments, a portion of the each pyramid microstructure 900 (e.g., a portion of the surface of each pyramid microstructure) may be magnetic such that a magnetic field applied to the LED array will orient the pyramid microstructures in the desired direction.

In certain embodiments, microstructures 800 and/or microstructres 900 in polymer material 410 are located only in the gap between LED devices 210 (e.g., there are no microstructures on top of the LED devices). If microstructures are in the polymer layer on top of LED devices 210, the microstructures may reflect back light emitted upward from the LED devices. Thus, having microstructures in the polymer layer only in the gap between LED devices 210 would limit light reflection to light emitted laterally from the LED devices 210. In certain embodiments, an LED structure without microstructures in the polymer layer above LEDs 210 is formed using steps similar to the embodiment depicted in FIG. 4B. For example, patterned mask 420 may be positioned over polymer layer 410 containing microstructures 800 and/or microstructres 900. Mask 420 may include additional openings at the locations over the LED devices to allow the removal of polymer layer 410 containing microstructures 800 and/or microstructres 900 above the LED devices. In some embodiments, an additional polymer layer is formed over LED devices 210 to form a polymer layer above the LED devices without microstructures.

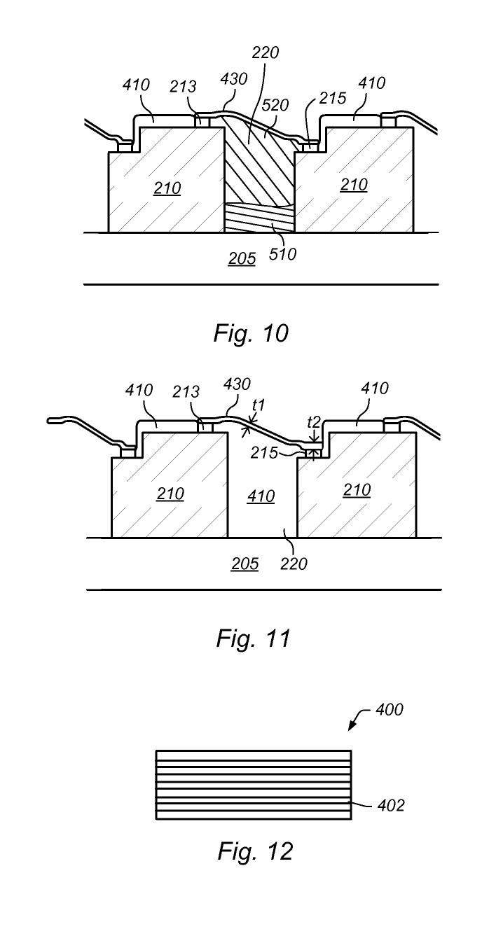

FIG. 10 illustrates an embodiment of an LED array with two polymer materials filling gap 220 between two LED devices 210. In some embodiments, a bottom portion of gap 220 (e.g., the portion above the surface of substrate 205) is more difficult to fill than an upper portion of the gap. For example, it may be more difficult to fill a bottom portion of gap 220 between LED devices 210 that include a plurality of vertically stacked epitaxial structures (for example, the plurality of vertically stacked epitaxial structures described in the embodiment depicted in FIG. 12). Using the plurality of vertically stacked epitaxial structures may increase the depth of gap 220 by 2, 3, 4, or more (e.g., 9) times the depth of a gap between single epitaxial structures. In embodiments with LED devices 210 having the plurality of vertically stacked, gap 220 may be deeper and more difficult to fill with a single polymer layer. Additionally, the bottom portion of the deep gap may be more difficult to fill than upper portions of the gap because of the vertical profile of LED devices 210, especially the bottom corners of the gap at the edges of the LED devices. Thus, using two or more polymer materials to fill the deep gap may provide advantageous properties for filling the gap. For example, a first polymer layer may have provide better filling of the bottom portion of the gap while a second polymer layer provides better optical properties and/or is less reactive with materials used during subsequent processing.

In certain embodiments, as shown in FIG. 10, the polymer layer filling gap 220 includes first polymer layer 510 and second polymer layer 520. First polymer layer 510 may be deposited first in gap 220 followed by second polymer layer 520. In certain embodiments, first polymer layer 510 is a different material than second polymer layer 520. In some embodiments, second polymer layer 520 includes two or more polymer layers (e.g., two or more additional polymer layers of the same or of different materials). In certain embodiments, second polymer layer 520 (or an upper layer of the second polymer layer) is used to form polymer layer 410 above LED devices 210. In some embodiments, an additional polymer layer is formed over LED devices 210 to form polymer layer 410 above the LED devices.

In some embodiments, second polymer layer 520 includes polymer material pre-mixed with phosphor. In some embodiments, second polymer layer 520 includes polymer material pre-mixed with an infrared radiating material. The infrared radiating material may include, for example, ceramic and/or a carbon-based nanostructure. In some embodiments, a surface hydrophilic modification process (e.g., oxygen plasma) is performed on a top surface of second polymer layer 520 to transform the top surface from a hydrophobic surface into a hydrophilic surface.

In certain embodiments, first polymer layer 510 and/or second polymer layer 520 includes photoresists. In one embodiment, first polymer layer 510 is a PMGI layer and second polymer layer is an SU-8 layer. The optical transparency of first polymer layer 510 and/or second polymer layer 520 may be equal to or more than 90% (e.g., equal to or more than 99%). The refractive index of first polymer layer 510 and/or second polymer layer 520 may range from 1 to 2.6.

In certain embodiments, first polymer layer 510 has a better filling characteristic than second polymer layer 520. For example, first polymer layer 510 may have a lower kinematic viscosity than second polymer layer 520. In certain embodiments, first polymer layer 510 has a kinematic viscosity that is less than or equal to about 500 centiStokes (cSt), less than or equal to about 300 cSt, or less than or equal to about 100 cSt. The difference in filling characteristic (e.g., the kinematic viscosity) may allow, for example, first polymer layer 510 to conform better to sloped sidewalls than second polymer layer 520.

In some embodiments, a reactivity of first polymer layer 510 with a developer is more than that of second polymer layer 520. In such embodiments, second polymer layer 520 may serve as a barrier layer on top of first polymer layer 510 to inhibit first polymer layer from reacting with one or more developers in subsequent photoresist processes. One such photoresist process may be forming interconnect 430 by metal sputtering in which an NR-7 patterning photoresist is used. First polymer layer 510 may have a greater reactivity with the developer used with the NR-7 photoresist than second polymer layer 520. Thus, the developer used with the NR-7 photoresist may react with first polymer (e.g., PMGI) layer 510 if not for the protection of second polymer (e.g., SU-8) layer 520.

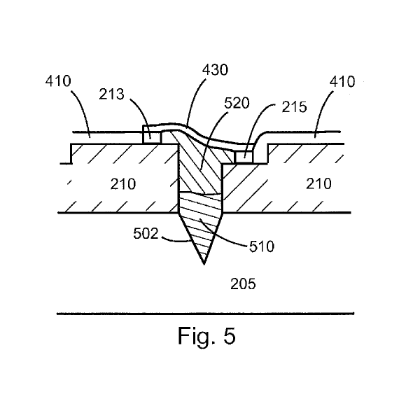

FIG. 5 illustrates an embodiment of an LED array with trench 502 formed in substrate 205 between two LED devices 210. Trench 502 is typically laser etched into the substrate during the formation of the gap between two LED devices 210 in order to allow more light to come out the lateral sides of the LED devices. As a result of the trench formation, light extraction efficiency of a whole LED chip that incorporates an array of LED devices 210 will be increased. The deeper trench 502 is, the higher the light extraction efficiency the LED chip may attain. Typically, a depth of trench 502 measured from an original surface of substrate 205 to the bottom of trench 502 is controlled at a range between 20 microns and 100 microns.

However, trench 502 may be more difficult to fill. Thus, in certain embodiments, as shown in FIG. 5, first polymer (e.g., PMGI) layer 510 is first deposited in trench 502 and followed by second polymer (e.g., SU-8) layer 520. First polymer layer 510 may have a better filling characteristic (e.g., a lower kinematic viscosity) than second polymer layer 520. For example, first polymer layer 510 may conform better to sloped sidewalls than second polymer layer 520. As described above, second polymer layer 520 deposited on top of first polymer layer 510 may also serve as a barrier layer protecting the underneath first polymer layer from reacting with developers in subsequent photoresist processes. In some embodiments, however, for example, if interconnect 430 is formed by a silver paste in a printing process, a single first polymer (e.g., PMGI) layer 510 can be used for filling the entire gap, including trench 502, between LED devices 210. Using a single PMGI layer may save on processing costs.

As described above, the smoothness of polymer layer 410 or second polymer layer 520 allows the sizes of the pads 213, 215 and interconnect 430 to be smaller than previous embodiments shown in FIG. 3. In certain embodiments, interconnect 430, formed over polymer layer 410 or second polymer layer 520, has selected properties that are allowed because of the smoothness of the polymer layer that may not be allowable if an oxide layer is used in the gap, as shown in FIG. 3. For example, as shown in FIG. 11, interconnect 430 may be have a thickness, t1, over gap 220 that is smaller than a thickness, t2, above pad 215 (and/or pad 213). In certain embodiments, a maximum of the thickness, t2, above pad 215 ranges between about 3 times and about 7 times a minimum of the thickness, t1, above gap 220. For example, in one embodiment, the maximum of the thickness, t2, above pad 215 is less than or equal to five times the minimum of the thickness, t1, above gap 220. Such differences in thicknesses are allowed because of the relatively smooth profile of the top surface of polymer layer 410 (or second polymer layer 520). The smooth profile of the polymer layer inhibits disconnects from forming at or around the edges of pads 213, 215, which would cause low conductivity in the interconnect. Thus, using the polymer layer in the gap improves the conductivity and reliability of the interconnect formed above the polymer layer.

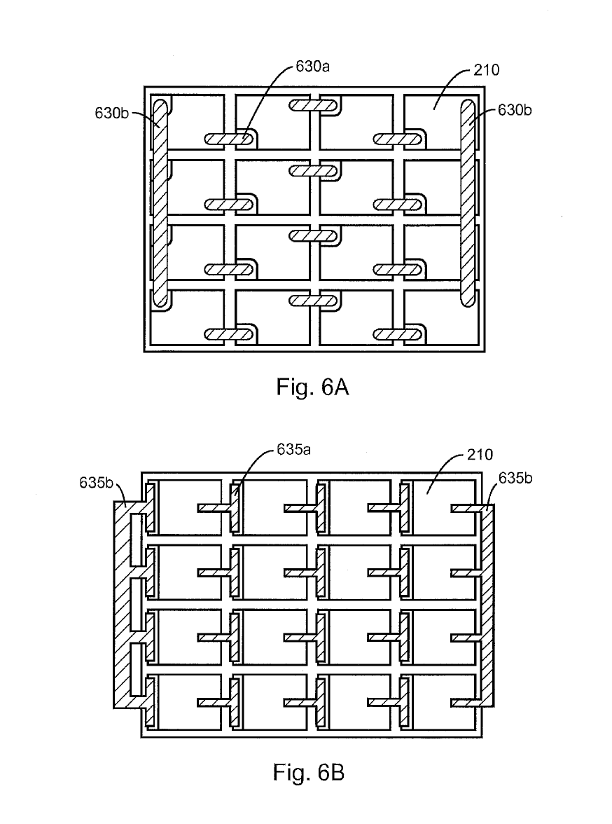

FIGS. 6A and 6B illustrate some alternative embodiments of patterns of interconnect 430. In some embodiments, as shown in FIG. 6A, interconnects 630a and 630b are moved to edges of LED devices 210 corresponding to relocations of electrode pads (not shown). In some embodiments, as shown in FIG. 6B, interconnects 635a and 635b are T-shaped to connect neighboring LED devices 210. Varying the interconnect patterns may reduce the area of the interconnects such that less light generated by the LED devices is shielded by the interconnects.

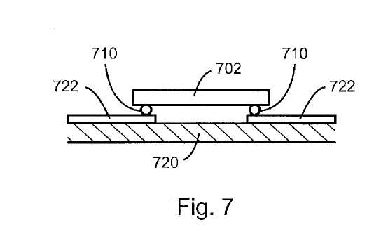

FIG. 7 illustrates an embodiment of LED chip 702 flip mounted on board 720. LED chip 702 may be produced through the embodiment of the process depicted in FIGS. 4A-4C (e.g., a plurality of LED devices 210 are formed on common substrate 205 (not shown in FIG. 7)). When substrate 205 is a sapphire substrate, which is highly transparent to light, LED chip 702 may be flip mounted on board 720. In such embodiments, substrate 205 of LED chip 702 is on the top and the plurality of LED devices 210 are below the substrate. Before the LED chip 702 is flip mounted on board 720, solder balls 710 are first formed on the terminals of LED chip 702. Then LED chip 702 is flipped over and placed on board 720 with solder balls 710 aligned to corresponding terminal interconnects 722. After a melting process, solder balls 710 bond LED chip 702 to board 720 through terminal interconnects 722. The flip-chip technology may yield the shortest board-level interconnects and better electrical characteristics. When multiple LED chips 702 are mounted on the same board 720, mounting density for the flip-chip mounting can be higher than conventional wire bonding. In addition, after LED chip 702 is flip mounted on board 720, the substrate (not shown in FIG. 7) on which the LED chip is grown can be removed for improved light emission.

In certain embodiments, LED devices 210 described herein include single epitaxial structures (e.g., each LED device includes a single light emitting layer). In some embodiments, LED devices 210 include a plurality of vertically stacked epitaxial structures (e.g., each LED device includes two or more light emitting layers in a vertically stacked structure). Vertically stacked epitaxial structures are described in U.S. patent application Ser. No. 13/442,422 entitled “COMPACT LED PACKAGE” to Heng et al. filed on Apr. 9, 2012, which is incorporated by reference as if fully set forth herein.

FIG. 12 depicts a side-view representation of LED unit 400 with vertically stacked epitaxial structures 402. In certain embodiments, LED unit 400 is used as LED device 210 described herein. In some embodiments, LED unit 400 is an LED array (e.g., the epitaxial structures in the LED unit are coupled to form the LED array). As shown in FIG. 12, LED unit 400 includes nine (9) vertically stacked epitaxial structures 402. Thus, a gap between LED devices that include LED unit 400 would be about 9 times a depth of a gap between LED devices that only include a single epitaxial structure. It is to be understood that the number of vertically stacked epitaxial structures may vary depending on, for example, a desired light output of LED unit 400 or manufacturing limitations.

LED unit 400 may be formed by vertically stacking epitaxial structures 402 using various stacking processes. In certain embodiments, each epitaxial structure 402 has at least a first doped layer, at least a light emitting layer, and at least a second doped layer. For example, epitaxial structure 402 may include an n-doped layer, a light emitting layer, and a p-doped layer.

In some embodiments, epitaxial structures 402 are vertically stacked using an epitaxial process. For example, LED unit 400 may be formed by epitaxially growing layers for each successive epitaxial structure 402 on top of each other to form the LED unit. In certain embodiments using the epitaxial process, a tunnel junction is formed between the bottom epitaxial structure and the top epitaxial structure (and/or between other epitaxial structures in the LED unit). The tunnel junction may be highly doped or polarization induced (either single film or multiplayer).

In some embodiments, epitaxial structures 402 are vertically stacked using a chip process. For example, LED unit 400 may be formed by bonding (coupling) individual epitaxial structures 402 together into a vertical stack to form the LED unit. In some embodiments, epitaxial structures 402 are coupled to each other with a bonding layer between the epitaxial structures. In some embodiments, the bonding layer is an adhesive layer, an oxide layer, and/or a metal layer.

Vertically stacking epitaxial structures 402 using either the epitaxial process or the chip process produces a vertical stack of epitaxial structures without any intervening substrate between the epitaxial structures. Having no intervening substrate between the epitaxial structures minimizes the height of LED unit 400 and simplifies connectability and/or operation of the LED unit.

In certain embodiments, epitaxial structures 402 in LED unit 400 emit substantially the same wavelength of light. In some embodiments, epitaxial structures 402 in LED unit 400 emit different wavelengths of light. For example, lower epitaxial structures in the LED unit may emit light with longer wavelengths than upper epitaxial structures. In some embodiments, epitaxial structures 402 in LED unit 400 are connected in series to form an LED array. In some embodiments, epitaxial structures 402 in LED unit 400 are connected in parallel to form an LED array. In some embodiments, epitaxial structures 402 in LED unit 400 are connected in a combination of series and parallel to form an LED array.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A light-emitting-diode (LED) array comprising:
a first LED unit having a first electrode;
a second LED unit having a second electrode, wherein the first LED unit and the second LED unit are positioned on a common substrate and are separated by a gap;
two or more polymer materials forming a multi-layered structure in the gap, wherein a first polymer material substantially fills a lower portion of the gap and at least one additional polymer material substantially fills a remainder of the gap above the first polymer material, and wherein a kinematic viscosity of the first polymer material is less than a kinematic viscosity of the at least one additional polymer material; and
an interconnect, positioned on top of the at least one additional polymer material, electrically connecting the first electrode and the second electrode.

2. The LED array of claim 1, wherein the kinematic viscosity of the first polymer material is less than or equal to about 500 centiStokes (cSt).

3. The LED array of claim 1, wherein the interconnect comprises a maximum thickness above at least one of the electrodes that is less than or equal to five times a minimum thickness of the interconnect above the gap.

4. The LED array of claim 1, wherein each of the first and second LED units comprises a plurality of vertically stacked epitaxial structures.

5. The LED array of claim 1, wherein a reactivity of the first polymer material with a developer is more than that of the at least one additional polymer material.

6. The LED array of claim 1, wherein at least one of the LED units comprises an epitaxial structure, and wherein the epitaxial structure comprises an n-doped layer, a light emitting layer, and a p-doped layer.

7. The LED array of claim 1, wherein at least one of the LED units comprises a plurality of vertically stacked epitaxial structures, the LED array further comprising a tunnel junction between any two of the plurality of vertically stacked epitaxial structures.

8. The LED array of claim 1, wherein at least one of the LED units comprises a plurality of vertically stacked epitaxial structures, the LED array further comprising a bonding layer between any two of the plurality of vertically stacked epitaxial structures.

9. The LED array of claim 1, wherein the first LED unit and the second LED unit are connected in series.

10. The LED array of claim 1, wherein the first LED unit and the second LED unit are connected in parallel.

11. The LED array of claim 1, wherein the two or more polymer materials comprise photoresist.

12. The LED array of claim 1, wherein the first polymer material is polymethylglutarimide (PMGI) and the at least one additional polymer material is SU-8.

13. The LED array of claim 1, wherein the at least one additional polymer material comprises photoresist pre-mixed with phosphor.

14. The LED array of claim 1, wherein a top surface of the at least one additional polymer material comprises a hydrophilic surface.

15. The LED array of claim 1, wherein the at least one additional polymer material is pre-mixed with an infrared radiating material.

16. The LED array of claim 1, further comprising a board, wherein the LED array is flip mounted on the board with the common substrate being above the first and second LED units.

17. The LED array of claim 16, wherein the LED array is flip mounted on the board with the common substrate removed.

18. A method for forming a light-emitting-diode (LED) array, comprising:
forming an LED structure on a substrate;
dividing the LED structure into at least a first LED unit and a second LED unit with a gap between the first LED unit and the second LED unit;
depositing a first polymer material into the gap between the first LED unit and the second LED unit to substantially fill a lower portion of the gap;
depositing at least one additional polymer material to substantially fill a remainder of the gap above the first polymer material; and
forming an interconnect on top of the at least one additional polymer material to electrically connect a first electrode of the first LED unit and a second electrode of the second LED unit.

19. The method of claim 18, wherein a kinematic viscosity of the first polymer material is less than a kinematic viscosity of the at least one additional polymer material.

20. The method of claim 18, wherein the kinematic viscosity of the first polymer material is less than or equal to about 500 centiStokes (cSt).

21. The method of claim 18, wherein each of the first and second LED units comprises a plurality of vertically stacked epitaxial structures.

22. The method of claim 18, wherein a reactivity of the first polymer material with a developer is more than that of the at least one additional polymer material.

23. The method of claim 18, wherein at least one of the LED units comprises an epitaxial structure, and wherein the epitaxial structure comprises an n-doped layer, a light emitting layer, and a p-doped layer.

24. The method of claim 18, wherein the first polymer material and the at least one additional polymer material comprise photoresist.

25. The method of claim 18, further comprising transforming a top surface of the at least one additional polymer material from a hydrophobic surface into a hydrophilic surface.
